(19) United States
(12) Patent Application Publication
(10) Pub. No.: US 2010/0155949 A1
(43) Pub. Date: Jun. 24, 2010

(54) LOW COST PROCESS FLOW FOR FABRICATION OF METAL CAPPING LAYER OVER COPPER INTERCONNECTS

(75) Inventor: Manoj K. Jain, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/343,915

(22) Filed: Dec. 24, 2008

(51) Int. Cl. H01L 23/52; H01L 21/4763

(52) U.S. Cl. 257/751; 438/626; 257/766; 257/762; 257/E23.141; 257/E21.496

(57) ABSTRACT

Semiconductor devices and methods are disclosed for improving electrical connections to integrated circuits. A process flow and device with a dual/single damascene interconnect structure overlying an existing interconnect structure in a semiconductor wafer is provided. A capping layer is formed thereon that comprises nickel/palladium layers within a bond pad opening. The layers are polished using a chemical mechanical polishing (CMP) technique so that the capping layers are within the opening.

### FIELD OF INVENTION

The present invention relates generally to semiconductor devices, and more particularly to fabricating a low cost passivation layer and metal capping layer over copper interconnects.

### BACKGROUND

Integrated circuits typically use multiple levels of conductive interconnects to electrically connect to various transistors and components. The top metal layer is commonly used for power distribution and requires lower sheet resistance, which may be achieved by using a lower bulk resistivity metal like copper, or by increasing the thickness of the top metal layer. Electrical connection to the integrated circuits are typically made by placing a bond wire or solder ball either directly over a bond pad, or on top of a capping metal layer deposited over the bond pad.

Lithography steps for patterning and etch steps can be relatively expensive in general. In addition, gold wire bonds on conventional aluminum capping layer form gold-aluminum inter-metallic compounds especially at higher temperatures, which lead to reliability issues due to Kirkendall voiding. Kirkendall effects can have practical consequences, such as the prevention or suppression of voids formed at the boundary interface in various kinds of alloy to metal bonding. For example, gold-aluminum inter-metallics are inter-metallic compounds of gold and aluminum that occur at contacts between the two metals. These inter-metallics have different properties than the individual metals which cause problems in wire bonding in microelectronics. For example, the main compounds formed at high temperatures are Au₅Al₂ (known as white plague) and AuAl₂ (known as purple plague). White plague formation causes low electric conductivity, so its formation at junctures can lead to an increase of electrical resistance causing inefficiency. Purple plague can generally lead to a growth of inter-metallic layers causing voids in the metal lattice. Accordingly, it would be desirable to fabricate metal layers with less expensive methods for patterning and etching while overcoming Kirkendall voiding issues.

### SUMMARY

The following presents a simplified summary of the invention in order to provide a basic understanding of some aspects of the invention. This summary is not an extensive overview of the invention. It is intended neither to identify key or critical elements of the invention nor to delineate the scope of the invention. Rather, its primary purpose is merely to present one or more concepts of the invention in a simplified form as a prelude to the more detailed description that is presented later.

The present disclosure relates to forming a top metal layer with a bond pad opening within a semiconductor wafer for providing electrical connection externally. An interconnect layer comprising a metal interconnect is formed on the semiconductor body and may be a single or multi-level interconnect layer. A dielectric layer is formed over the interconnect layer having a conductive via feature within a lower portion of the dielectric layer and a conductive trench feature within an upper portion of the dielectric layer. In addition, a bond pad is formed within an opening of the dielectric layer comprising a capping layer and optionally a barrier layer. The capping layer can comprise a nickel layer and/or a palladium layer. The opening extends to the conductive trench feature, and the barrier layer and capping layer are located inside the opening without substantial protrusion above a top surface of the dielectric layer.

To the accomplishment of the foregoing and related ends, the following description and annexed drawings set forth in detail certain illustrative aspects and implementations of the invention. These are indicative of but a few of the various ways in which one or more aspects of the present invention may be employed. Other aspects, advantages and novel features of the invention will become apparent from the following detailed description of the invention when considered in conjunction with the annexed drawings.

### BRIEF DESCRIPTION OF THE DRAWINGS

FIGS. 1A-1G are cross-sectional illustrations of a semiconductor device being formed according to prior art.

FIG. 2 is a flow diagram illustrating an exemplary methodology for forming a semiconductor device in accordance with one or more aspects of the present disclosure.

FIGS. 3A-3D are cross-sectional illustrations of a semiconductor device being formed according to one or more aspects of the present disclosure.

FIGS. 4A-4B are cross-sectional illustrations of a semiconductor device according to one or more aspects of the present disclosure.

### DETAILED DESCRIPTION

One or more aspects of the present disclosure are described with reference to the drawings, wherein like reference numerals are generally utilized to refer to like elements throughout, and wherein the various structures are not necessarily drawn to scale. It will be appreciated that where like acts, events, elements, layers, structures, etc. are reproduced, subsequent (redundant) discussions of the same may be omitted for the sake of brevity. In the following description, for purposes of explanation, numerous specific details are set forth in order to provide a thorough understanding of one or more aspects herein. It may be evident, however, to one of ordinary skill in the art that one or more aspects may be practiced with a lesser degree of these specific details. In other instances, known structures are shown in diagrammatic form in order to facilitate describing one or more aspects.

In the examples of this disclosure, the dimensions disclosed for via and metal line widths, as well as any other pattern dimensions disclosed herein unless otherwise expressly stated, are based upon the size of the pattern to be formed on the wafer. The actual dimensions for via and metal line width for the photomask patterns will vary depending upon the size of the reduction factor of the photomask. Photomasks are often formed to have, for example, a 4× or 5× reduction factors, meaning that the photomask pattern dimensions can be about 4 or 5 times larger than the corresponding dimensions formed on the wafer. Similarly, the dimensions of the drawn pattern may or may not also have a reduction factor. Therefore, as one of ordinary skill in the art would readily understand, the mask sizes and the drawn pattern sizes can correspond to the wafer dimensions based on any suitable reduction factor, including where the dimensions on the mask and/or drawn pattern dimensions are intended to be the same as those formed on the wafer.

The present disclosure relates to forming a semiconductor device with a damascene interconnect structure in a manner that facilitates lowering the number of steps and cost of the process flow while mitigating adverse effects associated with electrical connections to a capping metal layer. In particular, the connections to various transistors and components of integrated circuits (especially with single or multiple levels of conductive interconnects) can be improved with a capping layer that comprises a barrier layer, a nickel layer, and a palladium layer. Afterwards, a planarization process (e.g., chemical mechanical planarization) can be performed from the top of the wafer surface, leaving the barrier layer, nickel layer, and palladium layer only within an opening connecting the integrated circuits to the outside world.

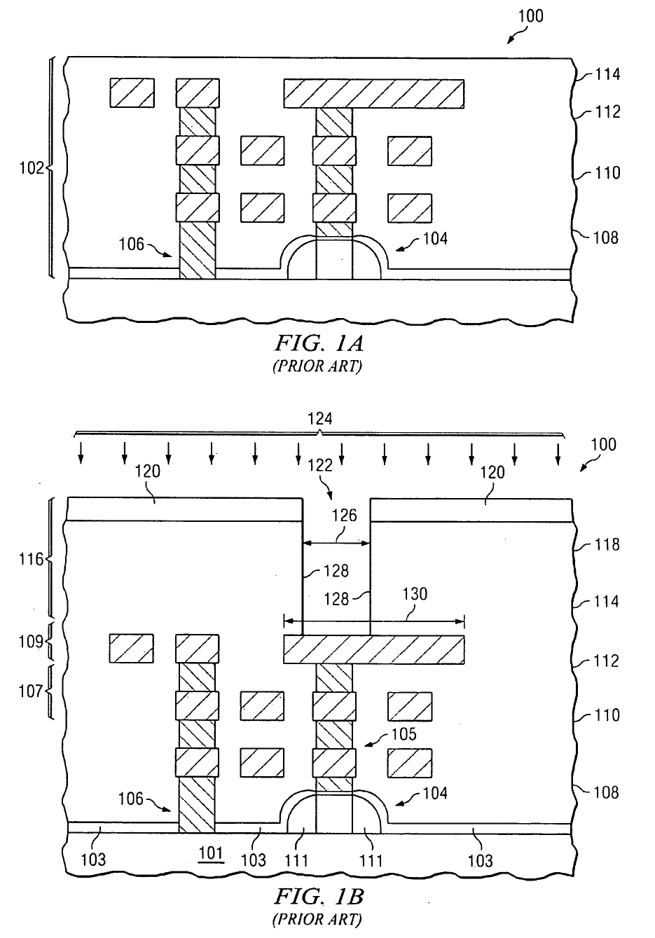

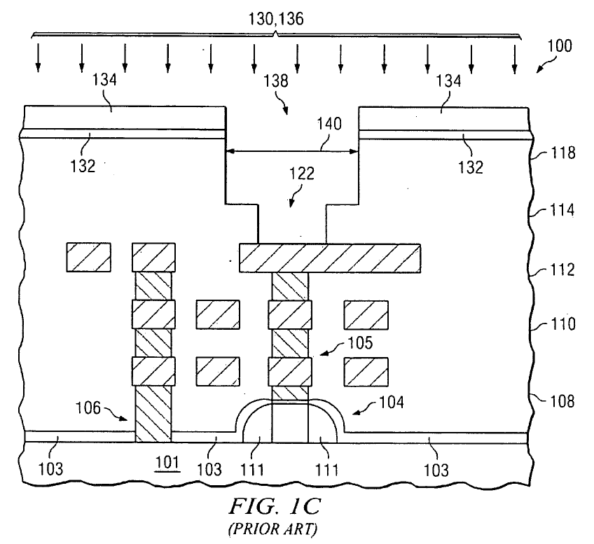

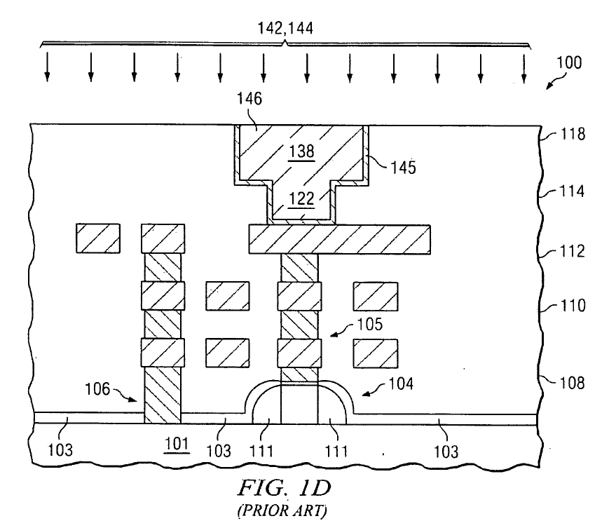

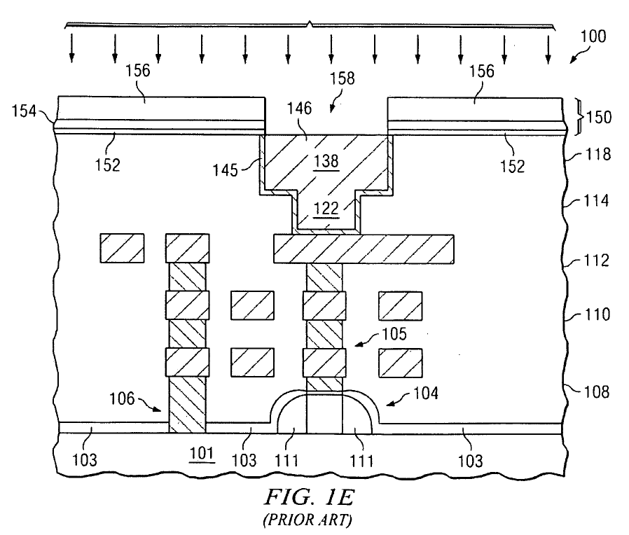

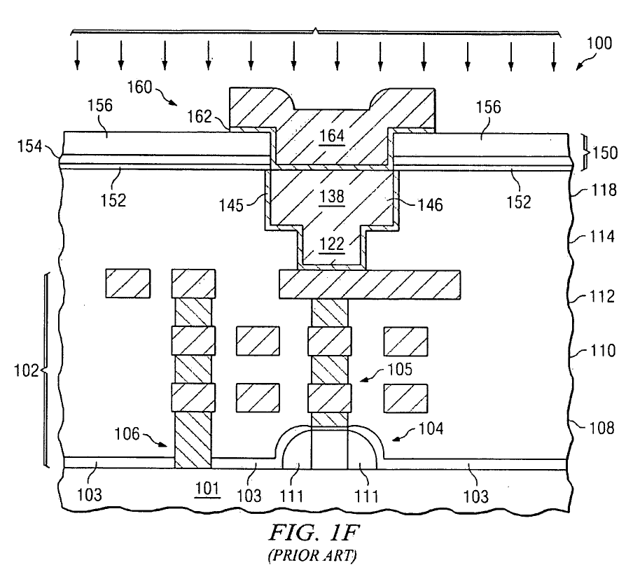

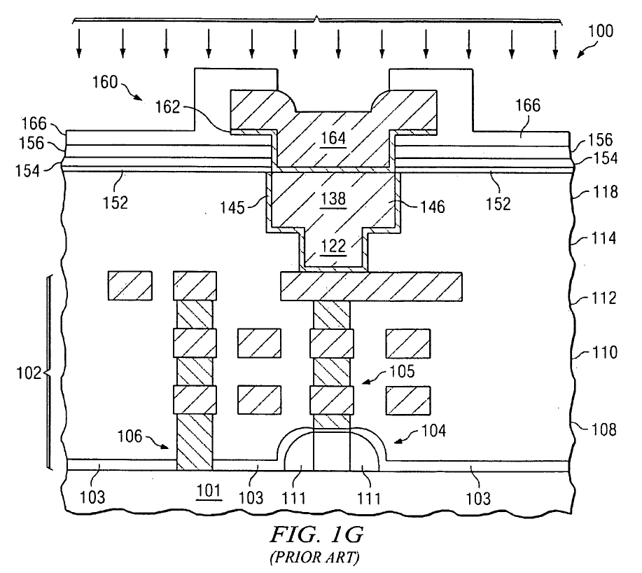

FIG. 1 A shows a back end of the line (BEOL) example of a metallization stack on a wafer 100 comprising a vertical hierarchy of alternating metal levels (M1, M2, M3) and via (i.e., stud) levels (V1, V2, V3) comprised within an inter-level dielectric material 102. The metal levels (M1, M2, M3) can provide horizontal interconnections between semiconductor devices 104, while the vias (V1, V2, V3) can provide vertical interconnections between various layers of the horizontal metal levels (e.g., V2 provides an interconnection between M1 and M2). The inter-level dielectric material 102 is comprised of a plurality of different dielectric layers (108, 110, 112, 114) that provide electrical insulation and electrical isolation between the metal and via levels.

Metal levels and vias are fabricated using separate lithography and etch steps. Using a Damascene process, such as a Dual/Single Damascene Process, for example, fabrication of the metal and via levels comprises forming a metal and via level within a deposited inter-level dielectric (ILD) material layer (e.g., silicon oxide, fluorinated silicon oxide, polymers including polyimide and fluorinated polyimide, ceramics, carbon and/or carbon doped dielectric materials, such as carbon silicate glass or organosilicate glass). During processing, the ILD layer is deposited and then holes (i.e., via holes) are patterned using known techniques such as the use of a photoresist material which is exposed to define a pattern. After developing, the photoresist acts as a mask through which the pattern of the ILD material is removed by a subtractive etch process (e.g., such as plasma etching or reactive ion etching) to partially form the via holes. A second patterning process proceeds to pattern metal wires. The pattern is also removed through a subtractive etch process which forms metal trenches and completes via hole etching such that the via holes extend from one surface of the ILD layer to the other surface of the ILD layer, while the metal trenches are comprised within the upper part of the ILD layer. The via holes and metal trenches are then filled in a metal deposition step to form both a via level and an abutting metal layer (e.g., the metal layer above the via). Metal may be deposited using a filling technique such as electroplating, electroless plating, chemical vapor deposition, physical vapor deposition or a combination of methods. This process may further include planarization of the metal by removing excess material with a method such as chemical mechanical polishing (CMP).

It is to be appreciated that silicon or semiconductor substrate as used herein can include a base semiconductor wafer or any portion thereof (e.g., one or more wafer die) as well as any epitaxial layers or other type of semiconductor layers formed thereover and/or associated therewith. The substrate can comprise, for example, silicon, SiGe, GaAs, InP and/or SOI. In addition, the substrate can include various device elements formed therein such as transistors, for example, and/or layers thereon. These can include metal layers, barrier layers, dielectric layers, device structures, including silicon gates, word lines, source regions, drain regions, bit lines, bases, emitters, collectors, conductive lines, conductive vias, etc. The metals can also be surrounded by diffusion barriers (not shown). The metals generally include copper or aluminum while the diffusion barriers may include tantalum, or a variety of other barriers, for example. It is to be appreciated that the substrate 102 can include one or more metallization layers that are not illustrated in addition to other non-illustrated device elements. Further, the metallization layer 106 may comprise one or more layers of metallization as may be desired.

FIG. 1B illustrates the wafer 100 comprising a silicon 101 that may or may not be silicided and a gate 104 is formed thereon with nitride sidewall spacers 111 adjacent to the gate on each side. An initial contact layer is formed over the silicon 101, comprising the dielectric 108 and a etch stop layer 103. A first interconnect structure is formed over the etch stop layer, comprising a dielectric 110 in which a conductive feature 105 is formed to provide electric coupling to the gate 104. This process may be repeated to provide electric coupling through a number of interconnect layers, such as with additional interconnect layers 107 and 109. A top layer 116 can be formed similarly with a dielectric layer 118 over an etch stop layer (not shown). The dielectric layer 11 8 can comprise one or more layers of materials, such as silicon nitride, silicon carbon-nitride, silicon dioxide, organosilicate glass (OSG), or doped silicon dioxide (with dopants such as boron, phosphorous or fluorine). In one example, an etch stop material (not shown) can be formed over interconnect layer 109 and the metals (M3, for example) with the dielectric layer 118 formed over top and optionally a layer of a hardmask material 120 can be formed over the dielectric layer 118. Layer 118 may include an oxide based material, whereas layer 120 may include silicon oxynitride and/or silicon carbide, silicon nitride, or silicon oxide, for example.

The layer of dielectric or capacitor ILD material 118 and optional layer of hardmask material 120 are patterned so that a cavity 122 (e.g., a via cavity) is formed therein over the metals. The cavity 122 can be formed by an etch process 124 in the layers 116 and 109, and stopping at the metal M3 and/or at an etch stop layer (not shown). It will be appreciated that the cavity 122 is formed so that a width 126 of the cavity 122 between sidewalls 128 can be equal to or smaller than a width 130 of the metal M3. As with all layers described herein (unless specifically indicated to the contrary), layers 118 and 120 can be patterned in any suitable manner, such as via etching and/or lithographic techniques. Lithography refers to processes for pattern transfer between various media. A radiation sensitive resist coating is formed over one or more layers to which the pattern is to be transferred. The resist is itself first patterned by exposing it to radiation, where the radiation (selectively) passes through an intervening mask containing the pattern. As a result, the exposed or unexposed areas of the resist coating become more or less soluble, depending on the type of resist used. A developer is then used to remove the more soluble areas leaving the patterned resist. The pattered resist can then serve as a mask for the underlying layers which can be selectively etched to transfer the pattern thereto.

In FIG. 1C, an optional planarizing layer 132 can be deposited to fill the via 122 and a trench resist mask 134 formed by an etch process 130 over the wafer 100. A trench etch operation 136 is performed to form a trench cavity or opening 138 having a width 140, for example. The planarizing layer 132 comprises a suitable organic/inorganic filling, or planarizing material such as bottom antireflective coating (BARC), hydrogen silsesquioxane (HSQ), or methyl silsesquioxane (MSQ), etc., for example. This planarizing layer material is intended to minimize the amount of photoresist from going into empty via holes. The optional planarizing material also helps protect the bottom of the via during etching of the trench 138 for the top metal level.

At FIG. 1D an ashing operation 142 and wet clean 144 can be performed to remove the layer material 134, and 132. A suitable barrier metal 145 such as TaN, Ta, bilayer TaN/Ta, Ti, TiN, bilayer Ti/TiN, WN, WSiₓN_{y}, or TiW can be deposited into the trench 138, and via 122. After, a copper seed 146 is deposited, copper is plated to fill the via 122 and trench 138. Copper can be removed from the top surface by a polishing procedure, such as CMP. Thus far, a dual damascene process has mostly been described, although a similar process can be performed for the top metal layer and top via structure by a single damascene process flow. Additionally, tungsten, copper and/or aluminum can fill the via 122 along with a suitable barrier as an option.

FIG. 1E illustrates an example of the formation of a passivation stack 150. The passivation stack 150 can be a single layer stack or a multiple layer stack. For example, the first layer may be a dielectric diffusion barrier 152 comprising at least one of silicon nitrate, silicon carbide, SIC, SICN, SIN, or SION, etc. that contacts the copper. The next layer can be an oxide layer 154 followed by the deposition of a top layer 156 comprising one or more of SIC, SICN, SIN, or SION, etc. Alternatively, the passivation stack 150 can comprise any number of layers capable of protecting the dye and provide a diffusion barrier. The passivation stack 150 can function as a hermetic seal that provides moisture sealing properties. For example, the passivation stack 150 can protect interconnects from harsh environmental conditions such as moisture attacks that can cause corrosion degrading performance or malfunction. Afterwards, patterning and etching processes may occur to make openings 158 where the integrated circuit can be connected to the outside world. These openings are referred to as PO openings.

FIG. 1F illustrates formation of a capping layer 160 comprising a barrier layer 162 and aluminum metal. The barrier layer 162 can be deposited, patterned and etched on top of the copper metal. This layer serves as a copper diffusion barrier and as such is may be formed from either a single layer barrier such as Ta, TiN, TaN, TiW, or a multilayer barrier such as Ta/TaN, TaN/Ti/TiN, or TaN/TiN, for example. Then, a layer of aluminum capping (ALCAP) material 164 is formed over the layer of barrier material. The layer 164 may include aluminum in conjunction with any other suitable material(s), and is generally formed to between about 7000 to about 30,000 (or 3 micron) angstroms, for example. In addition, an optional layer of TiN can be deposited over the aluminum layer, which can provide antireflective properties.

The layer of ALCAP material 164 and the layer of barrier material 162 are patterned, such as by patterning a resist (not shown) there-over, using the resist as a mask and then removing the patterned resist after exposed portions of the ALCAP layer 164 and barrier layer 162 have been etched away.

In FIG. 1G a layer of a protective capping or overcoat material (PO2) layer 166 is formed. This layer serves to protect the aluminum metal from harsh environmental conditions, and can be a second passivation dielectric stack formed in a similar manner to the dielectric stack 150 of FIG. 1E in which the etch stop layer can be optional for the ALCAP. The protective capping layer 166 is deposited, patterned and etched as shown in FIG. 1G. An opening is also patterned down to the ALCAP material for connection to the outside. The fabrication flow can then continue for further back end processing. It should be noted that the ALCAP material contacting top metal segment can be a bond pad connection. The layers are not drawn to scale (in relative width) in these Figures. In addition, the process illustrated in FIGS. 1E, 1F, and 1G can apply to both a single damascene formation and/or dual damascene formations as one of ordinary skill in the art would appreciate and is not limited to either one process. Further, the via material can comprise tungsten, as well as copper or aluminum. The illustrations are merely examples of how a process flow can be carried out.

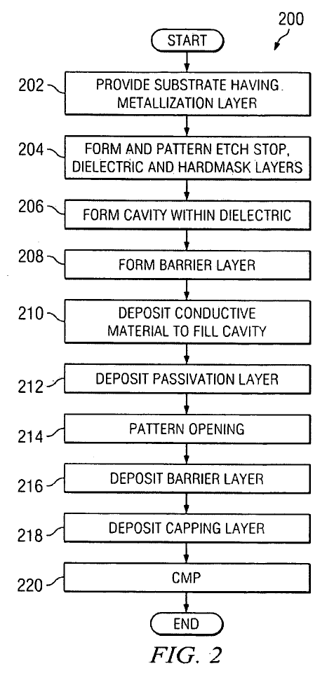

Referring now to FIG. 2, an exemplary method 200 is illustrated and described hereinafter for fabricating passivation and metal capping layers over interconnects. Initially, a damascene interconnect structure is formed, such as a via or a trench for a dual damascene structure; however a single damascene structure can also be utilized as one of ordinary skill in the art would appreciate. Although the method 200 and other methods herein are illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated.

The exemplary method 200 is described hereinafter in the context of a damascene via formation in a semiconductor wafer. However, it will be appreciated that the exemplary method 200, and other damascene methodologies of the present invention, may be employed alternatively or in combination in forming a single damascene trench structure or a dual damascene via and trench structure. The method 200 comprises providing a silicon such as with a semiconductor wafer having a metallization layer with an existing interconnect structure 202. The method 200 further comprises forming an etch-stop layer over an existing interconnect structure at 204 (e.g., over a previous damascene structure or over an initial contact level), and forming a low-k dielectric layer over the etch-stop material. The interconnect structure can comprise various metals, such as aluminum and/or copper. Further, any appropriate etch-stop and dielectric materials and layer fabrication techniques may be employed at 204, respectively, such as depositing SiN or SiC etch-stop material to a predetermined thickness (e.g., from about 300 to 1500 Å), for example 600 angstroms, using any appropriate deposition technique such as chemical-vapor deposition (CVD) or the like. A hardmask or cap layer can be optionally used.

At 206 a cavity is formed within the dielectric to connect to the metallization layers within. The cavity can be a single via for single damascene structures or a via with a trench for dual damascene structures by processes known to one of ordinary skill in the art. A BARC (bottom anti-reflective coating) layer is optionally deposited comprising any appropriate organic material having anti-reflective properties to a predetermined thickness over the dielectric layer. Alternatively, any suitable organic/inorganic filling or planarizing material such as HSQ (hydrogen silsesquioxane) or MSQ (methyl silsesquioxane), etc. can be used to fill the via/trench. This optional planarizing material can minimize the amount of photoresist from going into empty via holes and help protect the bottom of the via during etching of a trench for the top metal layer, as with a dual damascene structure.

After trench formation a barrier layer at 208 can be formed with a suitable barrier material such as TaN, Ta, Ti, TiN, WN, WSiₓN_{y}, TiW, or bilayer TaN/Ta, or Ti/TiN. The barrier layer can be deposited into the trench and/or via. An electrochemical deposition (ECD) process is then performed at 210 to deposit a conductive layer (e.g., copper) over the wafer, which fills the cavity (e.g., via and/or trench), and overlies the barrier layer on top of the remaining dielectric to form a top metal layer. Any appropriate copper deposition process may be employed, which may be a single step or a multi-step process in order to fabricate this top metal region. Thereafter, a chemical mechanical polishing (CMP) process can be performed to planarize (CMP) the upper surface of the device, which ideally stops on the dielectric layer and reduces the diffusion barrier and the deposited copper. In this manner, the planarization process electrically separates the conductive (e.g., copper) via from other such vias formed in the device, whereby controlled connection of the underlying conductive feature with subsequently formed interconnect structures can be achieved.

After fabrication of the top metal layer, a dielectric stack (e.g., a passivation stack) can be deposited at 212 comprising one or more layers of dielectrics such as silicon nitride, silicon dioxide or doped silicon dioxide (dopants such as phosphorous, boron, or fluorine, etc.) for example. The passivation stack can protect the interconnects from harsh environmental conditions such as moisture that can corrode or cause malfunction. At 214 a pattern and etch can be used to make openings (e.g., PO openings) where the integrated circuit can be connected externally.

Lithography steps for patterning and etch steps are relatively expensive Therefore, a lower cost process flow is embodied. For example, the method 200 then continues at 216 with depositing a diffusion barrier layer such as a barrier metal comprising a single layer TaN, Ta, Ti, TiN, WN, WSiN, TiW, TiWN, or a single layer or multilayer barrier with two or more of these elements, such as TaN/Ta, TiW Ti/TiN, etc. Any barrier substance and/or metal is embodied that is capable of preventing diffusion of the conductive material (e.g., copper) into a metal stack deposited thereabove.

In one embodiment, a capping layer is deposited at 218 on top of the barrier layer formed at 216. The capping layer can comprise a palladium layer, a nickel layer and/or a palladium layer and a nickel layer. In other words, the capping layer can comprise at least one of a palladium layer and a nickel layer. In one embodiment, the nickel layer can be deposited first and thereafter the palladium layer can be deposited thereon. The nickel layer can comprise a thickness between about 20 nm to 5000 nm (e.g., 100 nm), and can be deposited on top of the barrier layer formed at 216. The palladium layer can comprise a thickness between about 50 nm to 2000 nm (e.g., 1000 nm) and can be deposited on top of the nickel layer. The nickel and/or palladium layers can be deposited either by an electroplating process, or electroless plating process, or sputter deposition.

In one embodiment, the barrier layer, nickel layer and/or palladium layer can be removed after deposition by CMP at 220. The CMP process can be from the top of the wafer surface, and above the dielectric layer (e.g., passivation stack/layer), thereby leaving these metals (nickel and/or palladium) only in the opening without substantial protrusion above the top surface of the semiconductor wafer and/or the dielectric layer formed in 212, after which the method 200 ends.

The method 200 uses less patterning and etch process steps than prior processes and thereby can reduce the cost of fabrication. In addition to the cost advantage, the nickel/palladium capping layer offers the advantage of more reliable bonding by reducing issues related to Kirkendall voiding, for example.

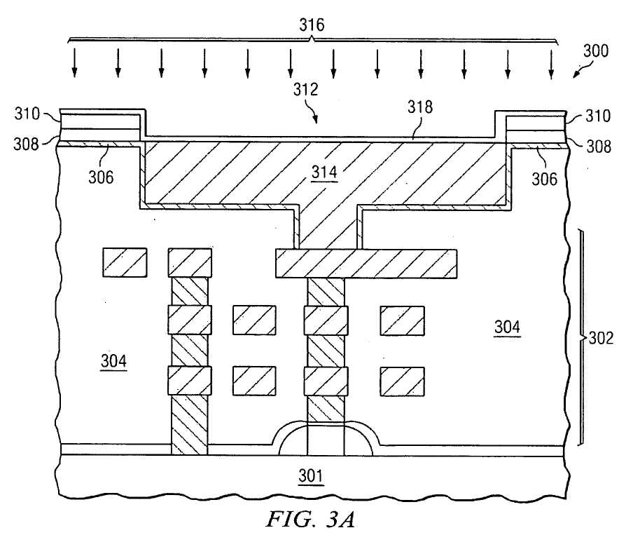

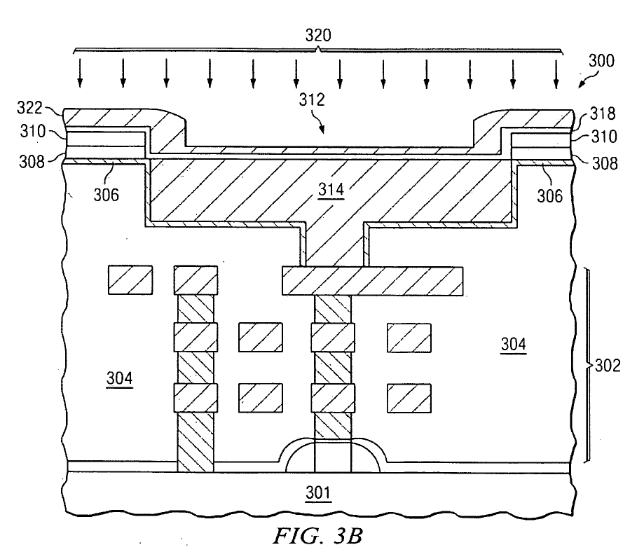

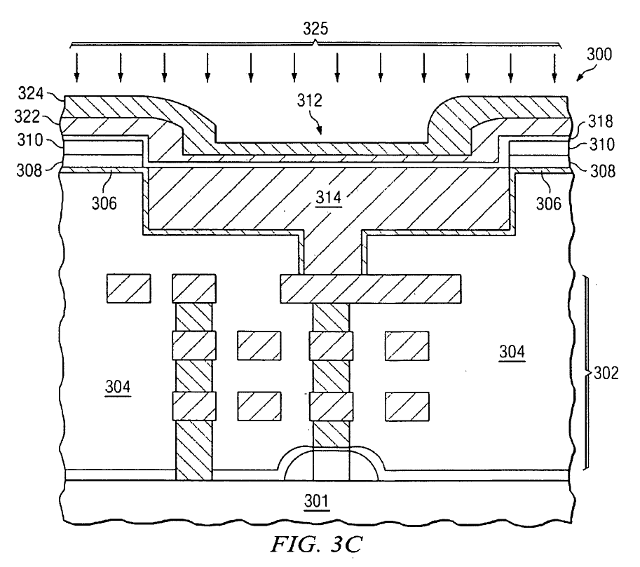

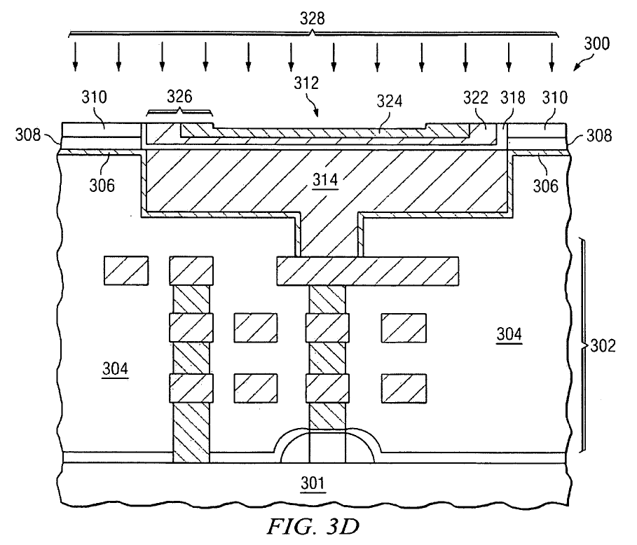

FIG. 3A illustrates an example of one embodiment of a semiconductor device. A metallization stack is illustrated from a back end of the line (BEOL) process on a wafer 300 comprising a vertical hierarchy of alternating metal levels and via (i.e., stud) levels comprised within an inter-level dielectric material 302. The metal levels (M1, M2, M3) can provide horizontal interconnections between semiconductor devices, while the vias (V1, V2, V3) can provide vertical interconnections between various layers of the horizontal metal levels (e.g., V2 provides an interconnection between M1 and M2). In one embodiment, the metals and vias can comprise copper and/or aluminum for conduction there between. The inter-level dielectric material 302 is comprised of a plurality of different dielectric layers that provide electrical insulation and electrical isolation between the metal and via levels. Although a single level or multi-layer interconnect may be described, the disclosure is not limited to either a single level or multi-layer interconnect device and can be implemented with either type of device.

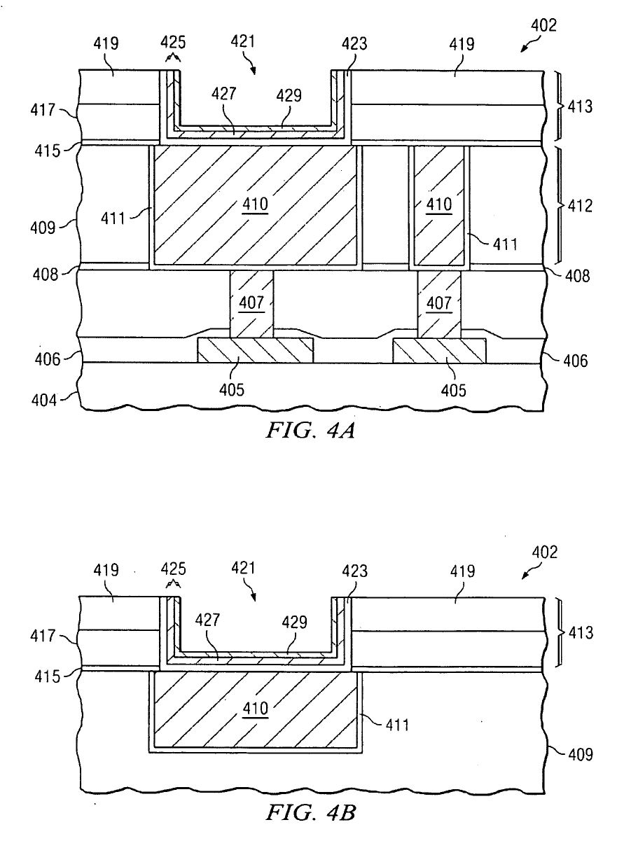

FIG. 3A illustrates a silicon 301, which may or may not be silicided and has been processed through formation of a topmost metallization layer 304. The passivation layer can be a single layer such as silicon nitride with a topmost metallization layer only or a multi-layer dielectric stack comprising a layer of an etch stop layer 306 such as a nitride, a layer of a dielectric material 308 and a layer of a hardmask material 310 or hermetic seal impervious to moisture, which can be sequentially formed over the wafer 300. The passivation layer can be patterned (e.g., etched) to form a bond pad opening 312, such as a PO opening therein that reveals a metal, such as copper 314. The PO opening may be equal or smaller than the metal below. In one embodiment, a barrier layer 318 is deposited upon the metal copper, for example. Through a deposition 316, the barrier layer 318 is deposited and can comprise a single layer TaN, Ta, Ti, TiN, WN, WSiN, TiW, TiWN, or a multilayer barrier of TaN/Ta, TiW Ti/TiN, etc. Any barrier substance and/or metal is embodied that is capable of preventing diffusion of the conductive material (e.g., copper 314) into a metal stack deposited thereabove. Although vias V1, V2 and V3 are illustrated underneath the metals M3, M2, and M3, and the bond pad 312, the vias may also be away from the bond pad opening 312 and not necessarily directly below the bond pad opening 312. This alternative is illustrated further in FIG. 4b, as discussed below.

FIG. 3B illustrates a continued process flow of one embodiment of the wafer 300. FIG. 3B illustrates deposition 320 of a nickel layer 322. The nickel layer 322 can be deposited either by an electroplating process, an electroless plating process, or by sputter deposition. In one embodiment, the nickel layer 322 can be of a thickness between about 20 nm to 5000 nm, e.g., 1000 nm.

FIG. 3C illustrates one embodiment of an additional deposition 325 of a palladium layer 324 overlying the nickel layer 322. The palladium layer 324 can be deposited either by an electroplating process, an electroless plating process, or by sputter deposition, similar to the nickel layer there below. In one embodiment, the layer of palladium can be thickness between about 50 nm to 2000 nm.

FIG. 3D illustrates the exemplary semiconductor device 300 comprising a bond pad opening 327 that comprises a barrier layer and a capping layer 326 overlying copper interconnects. After the barrier layer 318, nickel layer 322, and palladium layer 324 are deposited on the device and within the opening 312, the layers are removed from the top of the surface by using a chemical mechanical planarization (CMP) process 328, leaving these layers 318, 322, and 324 only in the opening 312. In one embodiment, the capping layer 326 can comprise aluminum with or without a barrier underneath, or nickel and palladium with or without a barrier underneath. In one embodiment, the barrier layer and capping layer are located inside the opening without protrusion above the top surface of the passivation stack (dielectric layer(s)) on top of the wafer.

FIG. 4A illustrates an exemplary structure of a semiconductor device with a single damascene structure comprising a capping layer over metal interconnects. The method discussed in FIG. 2 above can also be performed for a single damascene via structure as illustrated in FIG. 4A, as well as a dual damascene structure. For example, a dual damascene trench structure (not shown) can also be formed. Although vias may be illustrated underneath metal layers, and bond pad openings, the vias may also be formed away from any bond pad opening and not necessarily directly below the bond pad opening as illustrated and discussed herein.

FIG. 4A illustrates a wafer 402 in the completed stage of formation comprising a silicon 404, a conductive silicide structure 405. An initial contact layer is formed over the silicon 404, comprising a dielectric 406 with a metal via 407 (e.g., tungsten, aluminum, copper, etc.) extending therethrough, and electrically contacting the silicide 405. A previous interconnect structure can formed over the contact layer, comprising an etch stop layer 408 and a dielectric 409 in which a conductive feature (e.g., copper trench metal) 410 if formed to provide electric coupling to the metal via 407. A diffusion barrier 411 surrounds the conductive feature 409 to prevent diffusion of the metal. In one embodiment, the metal contact (via) can comprise aluminum, tungsten and/or copper, and the conductive feature (trench structure) can comprise copper. Any existing interconnect structure is envisioned by the inventors, such as single level or multi-layer interconnects.

A passivation stack (dielectric stack) 413 overlies a top metal layer 412 and can comprise a single layer or multiple layer interconnects. For example, the passivation stack 413 can comprise a layer of an etch stop material 415, a layer of a dielectric material 417 and a layer 419 of SIN, SION, SIC, or SICN, as discussed above supra with the passivation stack of FIG. 2. An opening or PO opening 421 is etched into the wafer 402 and layered with a barrier layer 423 and a capping layer 425. The capping layer 425 can comprise single or multiple layers. For example a nickel layer 427 can overlie the barrier layer 423, and a palladium layer 429 can overlie the nickel layer 427. A CMP process has been performed to planarize/polish the surface of the wafer thereby having the capping layer and barrier layer only within the PO opening 421. In one embodiment, there is no protrusion of the barrier layers and capping layers outside the opening and above the top surface of the wafer (above the layer 419). In addition, the capping layer can overlie the walls and bottom of the opening.

Although vias are illustrated underneath the metals, and the bond pad in FIG. 4A, FIG. 4B illustrates that the vias (not shown) may be away from the bond pad opening and not necessarily directly below the bond pad opening, but elsewhere.

The process flow for patterning and etching is reduced for fabricating the structures of FIGS. 4A-4B and FIGS. 3A-3D thereby reducing the cost of fabrication. In addition, gold-aluminum inter-metallic compounds produced when forming wire bonds can therefore be avoided, thereby reducing issues related to Kirkendall voiding. In addition, nickel/palladium layers offer the advantage of reliable bonding.

It will be appreciated that copper diffusion barriers, including those disclosed herein, are typically formed using conductive compounds of transition metals, such as tantalum, tungsten and titanium alone or in combination with their respective nitrides, carbonitrides, silicon nitrides and/or silicon carbonitrides (e.g., Ta, TaN, TaSiN, titanium nitride, tungsten nitride, silicon nitride, silicon oxynitride, silicon carbide). It will be appreciated, however, that any and all barrier materials with sufficient Cu barrier properties are contemplated as falling within the scope of the present invention.

Further, from time to time throughout this specification and the claims that follow, one or more layers or structures may be described as being or containing a substance such as “tungsten”, “copper”, “silicon nitride”, etc. These description are to be understood in context and as they are used in the semiconductor manufacturing industry. For example, in the semiconductor industry, when a metallization layer is described as containing copper, it is understood that the metal of the layer comprises pure copper as a principle component, but the pure copper may be, and typically is, alloyed, doped, or otherwise impure. As another example, silicon nitride may be a silicon rich silicon nitride or an oxygen rich silicon nitride. Silicon nitride may contain some oxygen, but not so much that the material's dielectric constant is substantially different from that of high purity stoichiometric silicon nitride.

Although one or more aspects of the invention has been shown and described with respect to one or more implementations, equivalent alterations and modifications will occur to others skilled in the art based upon a reading and understanding of this specification and the annexed drawings. The invention includes all such modifications and alterations and is limited only by the scope of the following claims. In addition, while a particular feature or aspect of the invention may have been disclosed with respect to only one of several implementations, such feature or aspect may be combined with one or more other features or aspects of the other implementations as may be desired and/or advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

Also, the term “exemplary” is merely meant to mean an example, rather than the best. It is also to be appreciated that layers and/or elements depicted herein are illustrated with particular dimensions relative to one another (e.g., layer to layer dimensions and/or orientations) for purposes of simplicity and ease of understanding, and that actual dimensions of the elements may differ substantially from that illustrated herein. Additionally, unless stated otherwise and/or specified to the contrary, any one or more of the layers set forth herein can be formed in any number of suitable ways, such as with spin-on techniques, sputtering techniques (e.g., magnetron and/or ion beam sputtering), (thermal) growth techniques and/or deposition techniques such as chemical vapor deposition (CVD), physical vapor deposition (PVD) and/or plasma enhanced chemical vapor deposition (PECVD), or atomic layer deposition (ALD), for example.

What is claimed is:

1. A semiconductor device comprising:
a semiconductor body;
an interconnect layer comprising a metal interconnect formed on the semiconductor body; and
a bond pad formed within an opening of the dielectric layer comprising a barrier layer, a capping layer or a barrier layer and a capping layer;
wherein the opening extends to the interconnect layer, and the barrier layer and capping layer are located inside the opening without substantial protrusion above a top surface of the dielectric layer so that the top surface is substantially planar.

2. The device of claim 1, wherein the capping layer comprises at least one of a nickel layer and a palladium layer.

3. The device of claim 1, wherein the barrier layer comprises a metal barrier layer below the capping layer comprising nickel and palladium.

4. The device of claim 1, wherein the capping layer comprises a palladium layer overlying a nickel layer.

5. The device of claim 1, wherein the capping layer comprises aluminum, and wherein the capping layer comprises a polished aluminum capping layer.

6. The device of claim 1, wherein the interconnect layer comprises copper.

7. A semiconductor device comprising:
a semiconductor body;
an interconnect layer comprising a metal interconnect formed on the semiconductor body;
a dielectric layer formed over the interconnect layer; and
a bond pad formed within an opening of the dielectric layer comprising a capping layer;
wherein the capping layer is located inside the opening without substantial protrusion above a top surface of the dielectric layer so that the top surface is substantially planar.

8. The device of claim 7, wherein the capping layer comprises at least one of a nickel layer, a palladium layer and wherein a barrier layer is below the capping layer, and the metal interconnect comprises copper.

9. The device of claim 1, wherein the capping layer comprises a palladium layer overlying a nickel layer.

10. A method of forming a semiconductor device having a damascene interconnect structure overlying an existing interconnect structure in a semiconductor wafer to provide electrical coupling to a conductive feature in the interconnect structure, the method comprising:
depositing a dielectric layer over the conductive feature;
forming a cavity within the dielectric layer;
depositing a barrier layer;
depositing conductive material to fill the cavity;
forming a passivation layer;
patterning an opening to the conductive material;
depositing a barrier layer;
depositing a capping layer; and
performing a CMP process leaving the barrier layer and capping layer only inside the opening.

11. The method of claim 10, wherein the cavity comprises a trench cavity and a via cavity within the dielectric layer for a dual damascene structure.

12. The method of claim 10, wherein the cavity comprises a via cavity only within the dielectric layer for a single damascene structure.

13. The method of claim 10, further comprising filling the cavity with a planarizing material.

14. The method of claim 10, wherein the conductive material comprises copper or aluminum.

15. The method of claim 10, wherein the capping layer comprises at least one of a nickel layer and a palladium layer.

16. The method of claim 10, wherein depositing a capping layer comprises:
depositing a nickel layer over the barrier layer; and
depositing a palladium layer over the nickel layer.

17. The method of claim 16, wherein the nickel layer has a thickness of between about 20 nm to 5000 nm, and the palladium layer has a thickness of between about 50 nm to 2000 nm.

18. The method of claim 10, wherein the capping layer comprises aluminum.

19. The method of claim 10, wherein forming the cavity comprises:
forming a via cavity;
depositing a planarizing material therein; and
forming a trench.
